(19) United States
(12) Patent Application Publication
(10) Pub. No.: US 2004/0145016 A1
(43) Pub. Date: Jul. 29, 2004

(54) Semiconductor apparatus incorporating MOS transistors with reduced narrow channel effect

(76) Inventor: Yoshinori Ueda, Hyogo-ken (JP)

Correspondence Address: DICKSTEIN SHAPIRO MORIN & OSHINSKY LLP, 2101 L STREET NW, WASHINGTON, DC, 20037-1526, US

(21) Appl. No.: 10/636,526

(22) Filed: Aug. 8, 2003

(30) Foreign Application Priority Data
Aug. 19, 2002 (JP) 2002-237914

(51) Int. Cl. H01L 27/01

(52) U.S. Cl. 257/347

(57) ABSTRACT

A semiconductor apparatus incorporating MOS transistors with reduced narrow or reverse narrow channel effect and a method for forming the semiconductor apparatus are disclosed. The semiconductor apparatus includes at least a field oxide layer for device isolation formed on a semiconductor substrate, a channel stopper region formed under the field oxide layer, and a MOS transistor of a first conductivity type electrically isolated by the field oxide layer and channel stopper region, in which the MOS transistor includes an impurity region for controlling narrow effect formed in the vicinity of both ends of a channel region in the direction of channel width, and a high concentration impurity region formed having an impurity concentration approximately equal to that of the channel stopper region at the location deeper than the channel stopper region. The MOS transistor can suitably be incorporated into a current mirror circuit, for example, to be included in semiconductor apparatuses such as a constant voltage generation circuit and a voltage detection circuit with improved precision.

### BACKGROUND

1. Field

This patent specification relates to a semiconductor apparatus and, more particularly, to such apparatus incorporating MOS transistors with reduced narrow channel effect and a method for forming the semiconductor apparatus.

This document claims priority and contains subject matter related to Japanese Patent Application No. 2002-237914, filed with the Japanese Patent Office on Aug. 19, 2002, the entire contents of which are hereby incorporated by reference.

2. Discussion of the Background

In the application of MOS (Metal Oxide Semiconductor) transistors to semiconductor circuits, it has been known that the narrow channel effect (or narrow effect) may result for decreased channel widths, caused by seeping out of impurity ions from a channel stopper region formed under a field oxide layer.

This narrow channel effect will be described herein below for an NMOS transistor in reference to FIGS. 11A and 11B.

FIG. 11A plots the threshold voltage Vₜₕ, vertically, as a function of the channel width W, horizontally, for an N-channel type MOS transistor. In similar manner for the N-type MOS transistor, FIG. 11B plots the saturation current Id, vertically, as a function of the channel width W, horizontally, at the applied gate voltage fixed to be approximately 1.0 volt which is frequently utilized in analogue circuits.

There referred to hereinafter are NMOS for N-channel type MOS transistor and PMOS for P-channel type MOS transistor, respectively.

Referring now to FIG. 11A, the threshold voltage Vₜₕ increases with decreasing channel width, which is indicative of the narrow channel effect.

In addition, although the saturation current without the narrow channel effect is expected to change linearly with channel width W (the dotted straight line shown in FIG. 11B), the actual feature of the change considerably deviates from the linear relation particularly in the range of decreased channel width (the solid curved line shown also in FIG. 11B), which is considered due to the undue effect from the decrease in the channel width on threshold voltage caused by the narrow channel effect.

This non-linearity may adversely affect on designing MOS transistor circuits, for example.

FIG. 12 is prepared to illustrate a current mirror circuit, and the adverse effects on circuit design, which is resulted from the noted non-linearity in the saturation current versus channel width relation, will be described in reference to FIG. 12.

The current mirror circuit is formed, as generally known, by connecting two or more transistors so that the current in one node is duplicated in the other. If the sources of two MOS transistors are tied together, and their gates are connected by one of the drains, the current in the first drain is duplicated in the second drain.

The current mirror circuit can therefore serve to generate current of the same magnitude or the desired current ratio in comparison with a reference source current, and widely used in analogue circuitry such as, for example, a constant biasing current source, constant current load and current ratio divider.

As an example, if the MOS transistors, Q1 and Q2, shown in FIG. 12, are designed to have the same channel length L and channel widths with a ratio of 1:10 for Q1 and Q2, the ratio of the resultant currents has to be I₁:I₂=1:10.

However, when the MOS transistors used in the decreased channel width range in which the narrow channel effect becomes evident as shown in FIG. 11B, the relation between the resultant currents becomes I₁:I₂>1:10, whereby errors in circuit design may arise.

As an attempt to alleviate such a drawback, the channel width of the MOS transistor Q1 might be increased as to be brought into the linearity region in which the saturation current changes linearly with the channel width. This method, however, naturally gives rise to the increase in resultant threshold currents, I₁ and I₂, which is disadvantageous to semiconductor devices such as, for example, LSI (large-scale integrated circuit) in use for cellular phones, for which power consumption as small as possible is desirable.

In addition, this method also gives rise to a further drawback such as the increase in the transistor size, which is again disadvantageous to the viewpoint of circuit pattern layout.

For the reasons indicated above, several methods have been devised to alleviate the narrow channel effect on MOS transistors.

As indicated earlier, this effect is considered to be physically caused primarily by impurity ions, which are originally included in a channel stopper region to serve to electrically isolate MOS transistors each other and to seep (or diffuse) out into the channel region in the MOS transistor.

FIG. 13 is a cross-sectional view along the channel width direction illustrating a previously known NMOS transistor.

Referring to FIG. 13, the NMOS transistor includes at least a field oxide layer 5 for device isolation formed on the surface of a P-type silicon substrate 1.

The impurities 6 for correcting threshold voltage such as, for example, boron ions are then introduced into a channel region included in an active region surrounded by the field oxide layer 5 to thereby form a channel stopper region 9.

In addition, a gate electrode 15 (which is hereinafter referred to as polysilicon gate) is formed over the channel region formed in the P-type silicon substrate 1 with a gate oxide layer 13 interposed there between.

As shown in FIG. 13, the channel stopper region 9 is formed entering to the channel region.

Since the impurities forming the channel stopper region 9 have a concentration higher than the impurities 6 for correcting threshold voltage, the impurity concentration increases in the edge portion of the channel region.

Such a feature of impurity seeping out from the channel stopper region 9 into channel region is known to give rise to the increase in threshold voltage with decreasing channel width, as shown earlier in FIG. 11A, that is, the narrow channel effect.

Disclosed previously in Japanese Laid-Open Patent Application No. 3-64946 is a method of alleviating the narrow channel effect.

In that method, the acceleration energy for ion implantation into the channel stopper region is increased to lower further the peak location of implanted ions, decrease the impurity concentration in the channel stopper in the vicinity of field oxide layer, and thereby reduce the impurity seeping out from the channel stopper region into the channel region.

In Japanese Laid-Open Patent Application No. 2-277847, a further method is disclosed, in which a silicon nitride layer is provided to form a pattern for defining the region for forming a field oxide layer, and sidewall spacers are then formed on the side faces of the pattern of the silicon nitride layer.

During the impurity introduction into the channel stopper region, these sidewall spacers are utilized so as to allocate a suitable distance between the region with introduced impurities and a forthcoming channel region, also to be used as a mask for the implantation of two kinds of ions each having different diffusion coefficients (such as, for example, arsine and phosphorus ions) as impurities into the channel stopper region such that high punch-through withstand voltages can be retained and that edge portions of active region of the transistor is predominated by the ions with the smaller diffusion coefficient, to thereby achieving a resultant low impurity concentration.

Thus, there have been disclosed the methods of lowering the peak location of implanted ions and providing sidewall spacers as offset regions during the impurity introduction into the channel stopper region and thereby allocating a distance suitable for suppressing the longitudinal impurity diffusion or seeping out from the channel stopper region into the active region.

In these methods, however, the width of resulting offset regions may tend to unduly fluctuate owning to several process factors in the course of following process steps such as oxide layer etching and heat treatment, thereby giving rise to difficulties in properly controlling the narrow channel effect.

In addition, one kind of impurities is often used both channel and channel stopper regions. In such circumstances, if the impurity concentration is increased to enhance the channel stop effect, the increase in seeping out into the channel region may be induced so as to result in the undue enhancement of the narrow channel effect.

By contrast, if the impurity concentration is decreased to suppress the narrow channel effect, the channel stop effect may also be reduced.

Therefore, the range of impurity concentration suitable for both channel stop and narrow channel effect is quite limited.

Furthermore, when the noted seeping out of the impurities in the channel stopper region into channel region is suppressed excessively, portions entirely deficient of the channel stopper region may arise around the edge portion of the channel region, as illustrated by the low concentration region 63 of FIG. 14.

In such a case, if the impurity concentration in the low concentration region 63 is lower than that in the channel region even after including the impurities 6 for correcting threshold voltage, the reverse narrow channel effect (or reverse narrow effect) is caused, in that the threshold voltage Vₜₕ decreases with decreasing channel width.

This reverse narrow channel effect is opposite to the narrow channel effect shown earlier in reference to FIG. 11.

Referring now to FIGS. 15A and 15B, the reverse narrow channel effect will be described herein below for an NMOS transistor.

FIG. 15A plots the threshold voltage Vₜₕ, vertically, as a function of the channel width W, horizontally, while FIG. 11B plots the saturation current Id, vertically, as a function of the channel width W, horizontally, at the applied gate voltage fixed to be approximately 1.0 volt which is frequently utilized in analogue circuits.

Referring to FIG. 15A, for the reverse narrow channel effect the threshold voltage Vₜₕ decreases with decreasing channel width, which is in contrast with the case shown earlier for the narrow channel effect in FIG. 11A.

In addition, although the saturation current without the reverse narrow channel effect is expected to change linearly with channel width W (the dotted straight line shown in FIG. 15B), the actual feature of the change considerably deviates from the linear relation particularly in the range of decreased channel width (the solid curved line shown also in FIG. 15B).

This non-linearity i.e., reverse narrow channel effect may adversely affect the precision of channel width ratio in a manner similar to that caused by the earlier noted narrow channel effect.

In addition, a further difficulty may arise in that a large number of transistors with decreased channel widths are used in a semiconductor apparatus of low power consumption, thereby possibly resulting in the undue increase in standby currents caused by the small channel widths.

Furthermore, when PMOS and NMOS transistors are both incorporated into a semiconductor circuit, the following case may arise. That is, by assuming that a first conductivity type of the transistors (for example, NMOS) are affected by the reverse narrow channel effect, and that the opposite conductivity type of transistors by the narrow effect, the balance of threshold voltages becomes worsened between these two types of the transistors, high for the one type and lower for the other.

This non-linearity, therefore, may give rise to a still further difficulty in designing MOS transistor circuits.

### SUMMARY

Accordingly, it is an object of the present disclosure to provide a semiconductor apparatus incorporating MOS transistors with reduced narrow or reverse narrow channel effect and a method for forming the apparatus, having most, if not all, of the advantages and features of similar employed apparatuses and methods, while eliminating many of the aforementioned disadvantages.

It is another object of the present disclosure to provide semiconductor apparatuses incorporating the MOS transistors disclosed herein, such as a mirror circuit with improved precision, for example, to be included in a constant voltage generation circuit and a voltage detection circuit.

The following description is a synopsis of only selected features and attributes of the present disclosure. A more complete description thereof is found below in the section entitled “Description of the Preferred Embodiments”.

A semiconductor apparatus disclosed herein includes at least a field oxide layer for device isolation formed on a semiconductor substrate, a channel stopper region formed under the field oxide layer, and a MOS transistor of a first conductivity type electrically isolated by the field oxide layer and channel stopper region, in which the MOS transistor includes an impurity region for controlling narrow channel effect formed in the vicinity of both ends of a channel region in the direction of channel width, and a high concentration impurity region formed having an impurity concentration approximately equal to that of the channel stopper region at the location deeper than the channel stopper region.

It may be added the noted first conductivity type will hereinafter be referred to either the P or N-type, while a second conductivity type is opposite to that of the first conductivity type.

In the MOS transistor, another impurity region for controlling narrow effect is formed preferably having the same kind, and the same concentration, of impurities as those of the impurity region for controlling narrow effect, in the region for forming another MOS transistor of a second conductivity type (opposite to that of the first conductivity type) in the vicinity of both ends of a channel region in the direction of channel width.

In addition, the impurities in the impurity region for controlling the narrow effect may have the conductivity type opposite to that of the high concentration impurity region.

Since the narrow effect controlling impurity region is provided in the region in the vicinity of both ends of the channel region in the direction of channel width of the MOS transistor, the reverse narrow channel effect or the narrow channel effect can be controlled by suitably adjusting the impurity concentration in the narrow effect controlling impurity region, and the MOS transistors unaffected either by the reverse narrow channel effect or the narrow channel effect can be fabricated.

According to another aspect, a further semiconductor apparatus is provided including a current mirror circuit which incorporate MOS transistors disclosed herein.

In addition, a further semiconductor apparatus is provided including an analog circuit consisting dividing resistors for dividing a voltage to be measured and supplying a divided voltage, a reference voltage source for supplying a reference voltage, and an operational amplifier for comparing the divided voltage with reference voltage, in which the operational amplifier includes at least the above noted current mirror circuit.

Since the MOS transistors disclosed herein is incorporated into the current mirror circuit and accordingly into the analog circuit, the precision in power output for these circuits can be improved.

According to still another aspect, a method for manufacturing the noted semiconductor apparatus is provided including the steps of

(A) forming an oxidation resistant coating for defining the region for forming the field oxide layer;

(B) implanting ions of a first impurity for controlling reverse narrow channel effect into the semiconductor substrate using the oxidation resistant coating as a mask, as a first implantation process;

(C) selectively forming a field oxide layer through heat treatment on the surface of the semiconductor substrate; and

(D) implanting ions of a second impurity from above the field oxide layer into the semiconductor substrate for forming a channel stopper region at the location deeper than the first impurity channel stopper region at least in the vicinity of both ends of the channel region in the direction of channel width of the MOS transistor, as a second implantation process.

The MOS transistor disclosed herein can therefore be fabricated including an impurity region for controlling narrow channel effect formed in the vicinity of both ends of a channel region in the direction of channel width, and a high concentration impurity region formed having an impurity concentration approximately equal to that of the channel stopper region at the location deeper than the channel stopper region.

In addition, the present method for manufacturing the noted semiconductor apparatus may alternatively be carried including the step of,

prior to the first implantation process (A), forming a well region of a first conductivity type and a further well region of a second conductivity type opposite to that of the first conductivity type; in which

the first implantation process (B) is implemented such that the ions of the first conductivity type are implanted, as the ions of the first impurity, into the well region of the first conductivity type and the further well region of the second conductivity type; and which

the second implantation process (D) is implemented with a mask pattern covering the region of the further well region of the second conductivity type such that the ions of the first conductivity type are implanted as the ions of the second impurity into the well region of the first conductivity type.

As a result, in the case where both NMOS and PMOS transistors are included, a first narrow effect controlling impurity region for the NMOS or PMOS transistor, and another narrow effect controlling impurity region for the PMOS or NMOS transistor, can be formed simultaneously. Therefore, the number of steps of device production decreases and the production costs can be reduced.

According to another aspect, a further method for manufacturing the noted semiconductor apparatus is provided including the steps of

(A) forming an oxidation resistant coating for defining the region for forming the field oxide layer and subsequently a field oxide layer selectively through heat treatment on the surface of the semiconductor substrate,

(B) forming a mask pattern having openings over the regions for forming a narrow effect controlling impurity region and the channel stopper region, and subsequently implanting ions of a first impurity for controlling the reverse narrow channel effect into the semiconductor substrate using the mask pattern as a mask, as a first implantation process, and

(C) implanting ions of a second impurity into the semiconductor substrate using the same mask pattern for forming a channel stopper region at the location deeper than the first impurity channel stopper region at least in the vicinity of both ends of the channel region in the direction of channel width of the MOS transistor, as a second implantation process.

The noted MOS transistors can therefore be fabricated unaffected by the reverse narrow channel effect or the narrow channel effect, and production costs can be reduced since ion implantation processes for forming the narrow effect controlling impurity region and high concentration impurity region are carried out using the same mask.

In addition, during the above noted methods the ions of the first impurity used in the first implantation process may have a conductivity type opposite to that of the second impurity used in the second implantation process.

As a result, the methods for manufacturing a semiconductor device disclosed may also be adapted to depletion-mode NMOS transistors by implanting impurity ions of the conductivity type opposite to that of ions of the channel stopper, whereby the reverse narrow channel effect or narrow channel effect can properly be suppressed.

The present disclosure and features and advantages thereof will be more readily apparent from the following detailed description and appended claims when taken with drawings.

### BRIEF DESCRIPTION OF THE DRAWINGS

FIG. 1 is a cross-sectional view in the direction of channel width illustrating a semiconductor device according to one embodiment disclosed herein;

FIGS. 2A through 2C are each cross-sectional views illustrating the method for manufacturing a semiconductor device during various stages in the process according to one embodiment disclosed herein;

FIG. 3A includes a graphical plot of device characteristics of the enhancement-mode NMOS fabricated according to one embodiment disclosed herein, the threshold voltage Vₜₕ, vertically, as a function of the channel width W, horizontally;

FIG. 3B includes a graphical plot of the threshold voltage Vₜₕ, vertically, as a function of the channel width W, horizontally, for the enhancement-mode NMOS of FIG. 3A;

FIGS. 4A through 4C are each cross-sectional views along the channel width direction illustrating the method for manufacturing a depletion-mode NMOS transistor during various stages in the process according to another embodiment disclosed herein;

FIGS. 5A through 5C are each cross-sectional views along the channel width direction illustrating the method for manufacturing semiconductor devices during various stages in the process including enhancement-mode NMOS and PMOS transistors;

FIGS. 6A and 6B plot the threshold voltage Vₜₕ, vertically, as a function of the channel width W, horizontally, for the PMOS and NMOS transistors including narrow effect controlling impurity regions disclosed herein;

FIGS. 6C and 6D are prepared for comparison for PMOS and NMOS transistors without the narrow effect controlling impurity regions, plotting the threshold voltage Vₜₕ, vertically, as a function of the channel width W, horizontally;

FIGS. 7A and 7B are each cross-sectional views along the channel width direction illustrating the portion of the method for manufacturing semiconductor devices during various stages in the process according to still another embodiment disclosed herein;

FIGS. 8A through 8D are each cross-sectional views along the channel width direction illustrating a further method for manufacturing a semiconductor device during various stages in the process according to another embodiment disclosed herein;

FIG. 9 is an electrical schematic diagram illustrating a semiconductor apparatus provided with a constant voltage generation circuit as an analogue circuit according to another embodiment disclosed herein;

FIG. 10 is an electrical schematic diagram illustrating a further semiconductor apparatus provided with a voltage detection circuit as an analogue circuit according to another embodiment disclosed herein;

FIG. 11A plots the threshold voltage Vₜₕ, vertically, as a function of the channel width W, horizontally, for a known N-channel type MOS transistor;

FIG. 11B plots the saturation current Id, vertically, as a function of the channel width W, horizontally, for the N-channel type MOS transistor of FIG. 11A;

FIG. 12 is prepared to illustrate a known current mirror circuit;

FIG. 13 is a cross-sectional view along the channel width direction illustrating a known NMOS transistor;

FIG. 14 is a cross-sectional view along the channel width direction illustrating a known NMOS transistor in which the seeping out of the impurities in the channel stopper region into channel region is suppressed excessively; and

FIGS. 15A and 15B are prepared to illustrate the reverse narrow channel effect plotting the threshold voltage Vₜₕ versus channel width W relation and the saturation current Id versus channel width W relation, respectively.

### DESCRIPTION OF THE PREFERRED EMBODIMENTS

In the detailed description which follows, specific embodiments of semiconductor apparatus are described, in which MOS transistors included therein are formed with reduced narrow or reverse narrow channel effect to suitably be incorporated into a current mirror circuit with improved precision. It is understood, however, that the present disclosure is not limited to these embodiments. For example, the use of the MOS transistors disclosed herein may also be adaptable to any form of electronic circuits and systems. Other embodiments will be apparent to those skilled in the art upon reading the following description.

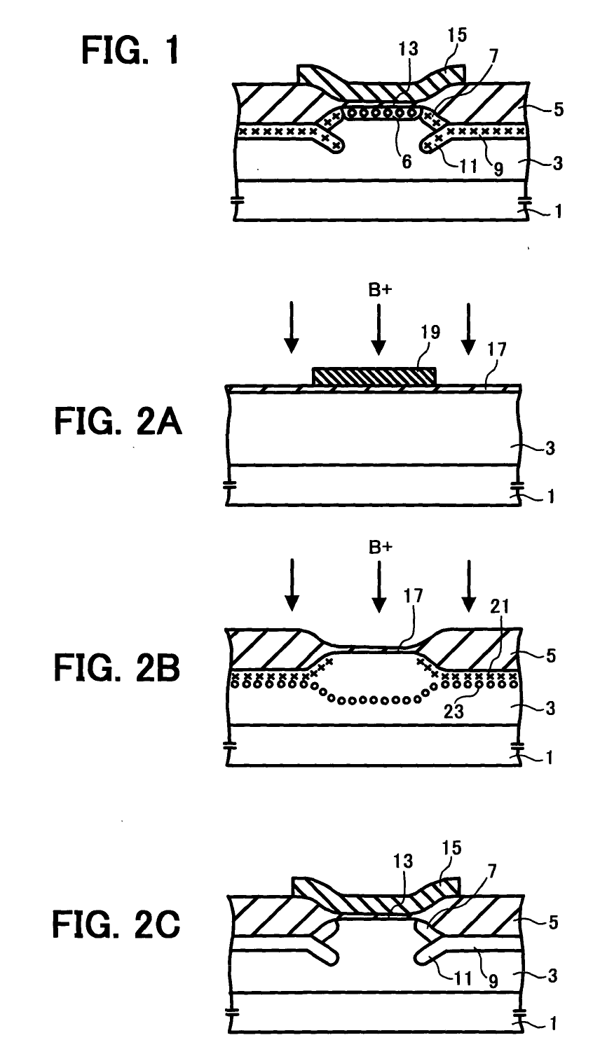

FIG. 1 is a cross-sectional view in the direction of channel width illustrating an enhancement-mode NMOS transistor as the semiconductor device according to one embodiment disclosed herein.

Referring to FIG. 1, a P-type drain well region 3 is formed in a P-type semiconductor silicon substrate 1 and a field oxide layer 5 for device isolation is formed on the substrate 1.

Subsequently, P-type impurities such as, for example, boron ions are introduced as the impurities 6 for correcting threshold voltage into a channel region included in an active region surrounded by the field oxide layer 5.

In addition, further P-type impurities such as, for example, boron ions are introduced to form a narrow effect controlling impurity region 7 into the region in the vicinity of both ends of the channel region in the direction of channel width.

A channel stopper region 9 is formed under the field oxide layer 5 by introducing boron ions, for example. In the region under the narrow effect controlling impurity region 7, a high concentration impurity region 11 is formed spatially separated from the channel region by introducing boron ions, for example.

The channel stopper region 9 has the approximately same impurity concentration as the high concentration impurity region 11, while the impurity concentration of channel stopper region 9 and high concentration impurity region 11 is larger than the narrow effect controlling impurity region 7.

In addition, a polysilicon gate 15 is formed over the channel region in the P-well region 3 with a gate oxide layer 13 interposed there between.

Since the channel region in the present NMOS transistor is formed spatially separated from the channel stopper region 9 and high concentration impurity region 11, seeping out of impurity ions to the channel region from the channel stopper region 9 and high concentration impurity region 11 is alleviated, whereby the narrow channel effect can be prevented.

Furthermore, since the narrow effect controlling impurity region 7 is provided in the region in the vicinity of both ends of the channel region in the direction of channel width of the MOS transistor, either the reverse narrow channel effect or the narrow effect can be controlled by suitably adjusting the impurity concentration in the narrow effect controlling impurity region.

Still further, the NMOS unaffected either by the reverse narrow channel effect or the narrow channel effect can be fabricated.

FIGS. 2A through 2C are each cross-sectional views along the channel width direction illustrating the method for manufacturing a semiconductor device during various stages in the process and FIG. 2C illustrates the fabricated enhancement-mode NMOS transistor as the semiconductor device according to one embodiment disclosed herein.

(1) Following the formation of a P-well region 3 in a P-type silicon substrate 1, a silicon oxide layer 17 is formed over the structure. In the present embodiment, a P-type silicon substrate having a resistivity of 20 Ω-cm and a P-type impurity concentration of approximately 6×10¹⁴ cm⁻³ is used as the silicon substrate 1, and the P-well region 3 is formed by introducing P-type impurities of a peak concentration of approximately 1×10¹⁷ cm⁻³ into the P-type silicon substrate 1.

A retro-graded well may alternatively be formed as the P-well region 3, which has the impurity concentration higher in the inside of, while lower on the surface of the substrate.

Since the impurity concentration in the vicinity of the substrate surface in this case becomes lower than previously known well region, the reverse narrow channel effect tends to form with more ease. As a result, the effect of suppressing the reverse narrow channel effect increases.

Subsequently, a silicon nitride layer is formed over the silicon oxide layer 17. The silicon nitride layer is then subjected to patterning steps to form an oxidation resistant coating 19. Using the oxidation resistant coating 19 as a mask, P-type impurities such as, for example, boron ions (B⁺) are implanted using ion implantation techniques (FIG. 2A). This ion implantation step constitutes the first ion implantation step in the semiconductor device fabrication method disclosed herein.

The conditions of ion implantation during the above noted process (1) are adjusted as an acceleration energy of 15 keV and a dose of 1.2×10¹³ cm⁻² so as to attain an implanted ion concentration one order smaller than that by the previous method of implanting collectively prior to field oxidation.

This is on the ground that the ion implantation herein is carried out for suppressing the reverse narrow channel effect rather than forming the channel stopper. Accordingly, the dose for the implantation is preferably adjusted approximately equal to, or smaller than 1.2×10¹³ cm⁻².

(2) After forming a field oxide layer 5 by the LOCOS (local oxidation of silicon) method on the surface of P-type silicon substrate 1, the oxidation resistant coating 19 is removed.

The boron ions implanted during the process (1) are therefore distributed in boron implanted region 21 (the region designated by the mark ‘X’) under the field oxide layer 5.

Subsequently, boron ions (B⁺) are implanted under the conditions of an acceleration energy of 180 keV and a dose of 1×10¹³ cm⁻².

The thus implanted boron ions are distributed in another boron implanted region 23 (the region designated by the mark ‘◯’). The depth of this region is determined by the thickness of overlying layers, that is, relatively shallow under the field oxide layer 5, while deeper under the silicon oxide layer 17 (FIG. 2B).

This ion implantation step constitutes the second ion implantation step in the semiconductor device fabrication method.

In addition, the impurity introduction for correcting threshold voltage into a channel region can be carried out under conditions properly determined depending on desired values of threshold voltage. This is exemplified by the ion implantation of P-type impurities such as, for example, boron ions under the conditions of an acceleration energy of 10 keV and a dose of approximately 3×10¹² cm⁻².

(3) Following the removal of the silicon oxide layer 17, a gate oxide layer 13 is formed to a thickness of approximately 7 nm on the surface of the channel region in the P-well region 3.

Subsequently, a polysilicon layer is formed over the structure and then subjected to patterning steps to form a polysilicon gate 15.

Furthermore, a source and drain regions (not shown) of MOS transistor are formed by the well known process, and subjected to heat treatment steps for activating the implanted ions.

As a result, there provided in the P-well region 3 are a channel stopper region 9 which is formed of the boron implanted regions 21, 23 under the field oxide layer 5, a narrow effect controlling impurity region 7 formed of the boron implanted region 21 in the region in the vicinity of both ends of the channel region in the direction of channel width, and a high concentration impurity region 11 formed of the boron implanted region 23 in the region under the narrow effect controlling impurity region 7 spatially separated from the channel region (FIG. 2C).

In the present embodiment, therefore, the channel region, channel stopper region 9, and high concentration impurity region 11 are formed spatially separated from each other. The NMOS transistor can therefore be formed including the narrow effect controlling impurity region 7 provided in the region in the vicinity of both ends of the channel region in the direction of channel width.

As a result, either the reverse narrow channel effect or the narrow channel effect is properly controlled, and the enhancement-mode NMOS can be fabricated unaffected by the reverse narrow channel effect or the narrow channel effect.

It may be added that during the process (2) for implanting boron ions for forming the boron implanted region 23 described earlier in reference to FIG. 2B, a mask pattern may be provided on the silicon oxide layer 17 so as to cover the channel region. Since no boron ion is implanted into the region under the channel region in this case, the structure shown in FIG. 1 can be formed.

As a result, by the impurity concentration in the region under the channel region thereby retained relatively low, the back bias effect can be suppressed, and this makes the countermeasures for low voltage capability feasible with more ease.

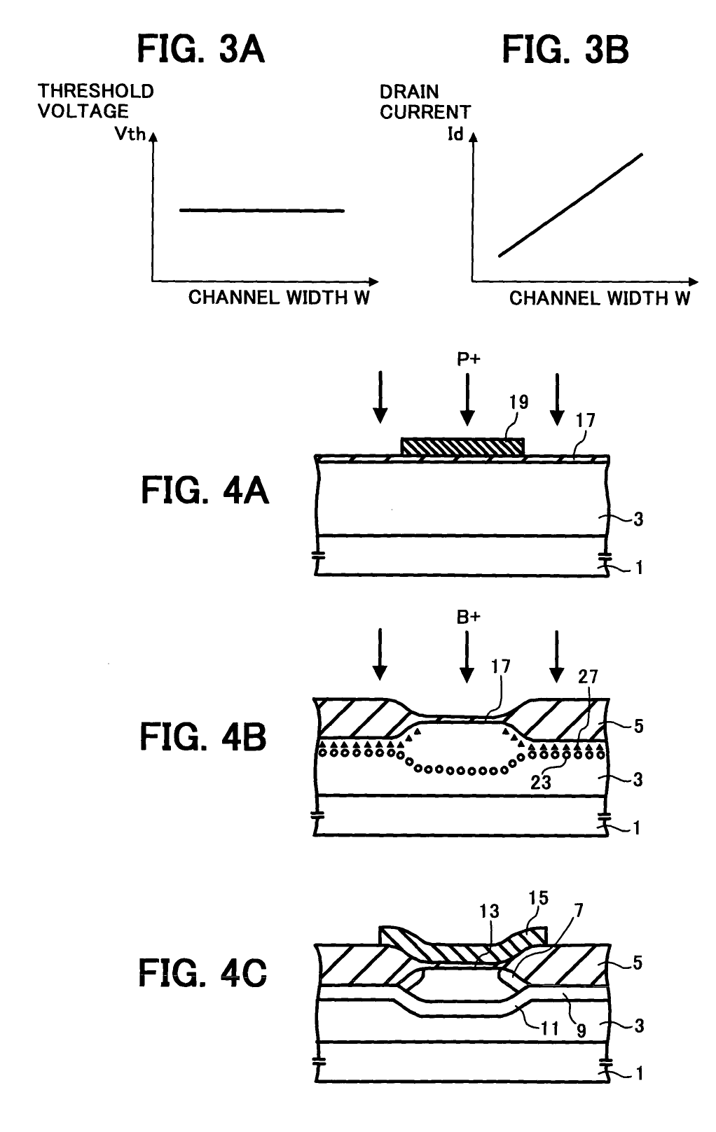

FIGS. 3A and 3B each include graphical plots of device characteristics of the enhancement-mode NMOS fabricated according to one embodiment disclosed herein, in which there plotted are the threshold voltage Vₜₕ, vertically, as a function of the channel width W, horizontally, in FIG. 3A; and the saturation current I_{d} as a function of W at a fixed applied voltage of approximately 1 volt in FIG. 3B.

As illustrated in FIG. 3A, the threshold voltage remains constant even decreased channel width W by suitably suppressing the reverse narrow channel effect or the narrow effect.

The linear relation of the saturation current versus channel width W is therefore provided, and this makes the circuit design of high precision analogue circuits feasible with more ease.

FIGS. 4A through 4C are each cross-sectional views along the channel width direction illustrating the method for manufacturing a semiconductor device during various stages in the process and FIG. 4C illustrates the fabricated depletion-mode NMOS transistor as the semiconductor device according to another embodiment disclosed herein.

In addition, the components in the drawings similar to those in FIGS. 2A through 2C are shown with identical numerical representations and detailed description thereof is herein abbreviated.

Referring now to FIG. 4C, a P-type drain well region 3 is formed in a P-type silicon substrate 1 and a field oxide layer 5 for device isolation is formed on the substrate 1.

Subsequently, the impurities for correcting threshold voltage (not shown) such as, for example, phosphorus ions are introduced in the vicinity of the surface region of P-well region 3 into a channel region included in an active region surrounded by the field oxide layer 5.

In addition, further P-type impurities such as, for example, phosphorus ions are introduced to form a narrow effect controlling impurity region 25 into the region in the vicinity of both ends of the channel region in the direction of channel width.

A channel stopper region 9 is formed under the field oxide layer 5 by introducing boron ions, for example.

In the region under the channel region and narrow effect controlling impurity region 25, a high concentration impurity region 11 is formed spatially separated from the channel region.

The channel stopper region 9 and the high concentration impurity region 11 each have an impurity concentration higher than the narrow effect controlling impurity region 25.

In addition, a polysilicon gate 15 is formed over the channel region in the P-well region 3 with a gate oxide layer 13 interposed there between.

Since the impurity ions introduced into the channel region are of N-type, seeping out of P-type impurity ions has a relatively large effect on the narrow channel effect can be prevented.

The channel region is formed spatially separated from the channel stopper region 9 and high concentration impurity region 11 in the present NMOS transistor. Therefore, the seeping out of impurity ions to the channel region from the channel stopper region 9 and high concentration impurity region 11 is alleviated, whereby the undue affect to the narrow channel effect can be prevented.

Furthermore, the narrow effect controlling impurity region 25 with the conductivity type opposite to that of the channel stopper region 9 and high concentration impurity region 11 is provided in the region in the vicinity of both ends of the channel region in the direction of channel width of the MOS transistor.

Therefore, either the reverse narrow channel effect or the narrow channel effect can be controlled by suitably adjusting the impurity concentration in the narrow effect controlling impurity region, whereby the depletion-mode NMOS unaffected by the reverse narrow channel effect or the narrow channel effect can be fabricated.

Referring now to FIGS. 4A through 4C, the method for manufacturing the NMOS transistor will be described according to another embodiment disclosed herein.

(1) Following the formation of a P-well region 3 in a P-type silicon substrate 1, a silicon oxide layer 17 is formed over the structure.

A silicon nitride layer is then formed over the silicon oxide layer 17. The silicon nitride layer is subsequently subjected to patterning steps to form an oxidation resistant coating 19.

P-type impurities such as, for example, phosphorus ions (P⁺) are implanted using ion implantation techniques under the conditions of an acceleration energy of 70 keV and a dose of ranging from 1×10¹² cm⁻² to 5×10¹² cm⁻² (FIG. 4A). This ion implantation step constitutes the first ion implantation step in the semiconductor device fabrication method disclosed herein.

Since the ion implantation herein is carried out for suppressing the reverse narrow channel effect, the dose for the implantation is preferably adjusted approximately equal to, or smaller than 2×10¹³ cm⁻².

(2) After forming a field oxide layer 5 by the LOCOS (local oxidation of silicon) method on the surface of P-type silicon substrate 1, the oxidation resistant coating 19 is removed.

The phosphorus ions implanted during the process (1) are therefore distributed in phosphorus implanted region 27 (the region designated by the mark ‘Δ’) under the field oxide layer 5.

Subsequently, boron ions (B⁺) are implanted under the conditions of an acceleration energy of 180 keV and a dose of 1×10¹³ cm⁻² to form a boron implanted region 23 (the region designated by the mark ‘◯’) as shown in FIG. 4B.

In addition, for introducing the impurities for correcting threshold voltage into a channel region, the conditions for the introduction can properly be determined corresponding to desired values of threshold voltage, which are exemplified by the ion implantation of N-type impurities such as, for example, phosphorus ions under the conditions of an acceleration energy of 70 keV and a dose of approximately 5×10¹² cm⁻².

(3) Following the removal of the silicon oxide layer 17, a gate oxide layer 13 is formed to a thickness of approximately 7 nm on the surface of the channel region in the P-well region 3.

Subsequently, a polysilicon layer is formed over the structure and then subjected to patterning steps to form a polysilicon gate 15.

Furthermore, a source and drain regions (not shown) of MOS transistor are formed by the well known process, and subjected to heat treatment steps for activating the implanted ions.

As a result, there provided in the P-well region 3 are a narrow effect controlling impurity region 25 which is formed of the phosphorus implanted region 27 in the region in the vicinity of both ends of the channel region in the direction of channel width, and a high concentration impurity region 11 formed of the boron implanted region 23 in the region under the narrow effect controlling impurity region 25 spatially separated from the channel region.

In addition, although the phosphorus implanted region 27 is formed under the field oxide layer 5 through the process (1) and the boron implanted region 23 through the process (2), the boron ion concentration is higher than phosphorus ions, whereby P-type channel stopper region 9 can be formed (FIG. 4C).

In the present embodiment, therefore, since the channel region, channel stopper region 9, and high concentration impurity region 11 are formed spatially separated from each other, the NMOS transistor can be formed including the narrow effect controlling impurity region 25 provided in the region in the vicinity of both ends of the channel region in the direction of channel width.

Therefore, either the reverse narrow channel effect or the narrow channel effect is properly controlled, and the depletion-mode NMOS can be fabricated unaffected by the reverse narrow channel effect or the narrow channel effect.

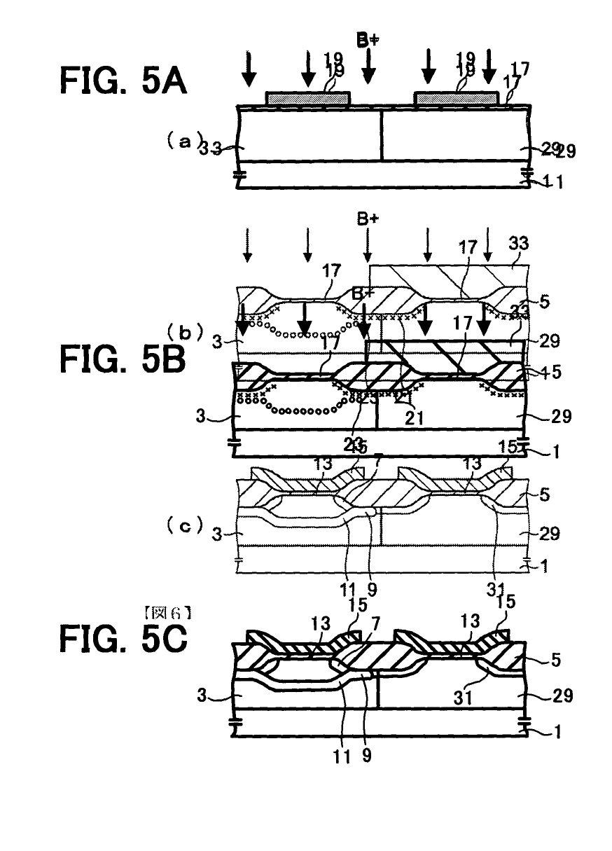

FIGS. 5A through 5C are each cross-sectional views along the channel width direction illustrating the method for manufacturing semiconductor devices during various stages in the process and FIG. 5C illustrates the fabricated enhancement-mode NMOS and PMOS transistors as the semiconductor devices according to still another embodiment disclosed herein.

In addition, the components in the drawings similar to those in FIGS. 2A through 2C are shown with identical numerical representations and detailed description thereof is herein abbreviated.

A P-well region 3 and an N-well region 29 are formed in a P-type silicon substrate 1 and a field oxide layer 5 for device isolation is formed on the substrate 1.

Subsequently, there formed in the P-well region 3 are a P-type narrow effect controlling impurity region 7 which is formed in the region in the vicinity of both ends of the channel region in the direction of channel width, a channel stopper region 9 which is formed under the field oxide layer 5, and a P-type high concentration impurity region 11 which is formed under the regions of the channel and narrow effect controlling impurity region 7.

In the N-well region 29, a narrow effect controlling impurity region 31 is formed by introducing P-type impurities such as, for example, boron ions into the regions such as in the vicinity of both ends of the channel region in the direction of channel width and under the field oxide layer 5.

The boron ions into the narrow effect controlling impurity region 31 are introduced simultaneously with those for forming the narrow effect controlling impurity region 7. The channel stopper region 9 and the high concentration impurity region 11 each have an impurity concentration higher than the narrow effect controlling impurity region 25.

The thus formed narrow effect controlling impurity region 31 constitutes the second narrow effect controlling impurity region in the semiconductor device disclosed herein.

In addition, polysilicon gates 15, 15 are formed over the respective channel regions in the P-well region 3 and N-well region 29 with gate oxide layers 13, 13 interposed there between.

In the present NMOS formed in the P-well region 3, in a similar manner to that for the NMOS previously described in reference to FIG. 2C, the channel region, channel stopper region 9, and high concentration impurity region 11 are formed spatially separated from each other, and narrow effect controlling impurity region 7 is formed in the region in the vicinity of both ends of the channel region in the direction of channel width.

Therefore, either the reverse narrow channel effect or the narrow channel effect is properly controlled, and the NMOS can be fabricated unaffected by the reverse narrow channel effect or the narrow channel effect.

Furthermore, the PMOS formed in the N-well region 29 is provided with a narrow effect controlling impurity region 31 in the vicinity of both ends of the channel region in the direction of channel width.

The reverse narrow channel effect or the narrow channel effect is therefore properly controlled, and the PMOS can be fabricated unaffected by the reverse narrow channel effect or the narrow effect.

Referring now to FIGS. 5A through 5C, the method for manufacturing the NMOS and PMOS transistors will be described according to another embodiment disclosed herein.

(1) Following the formation of an N-well region 29 and P-well region 3 in a P-type silicon substrate 1, a silicon oxide layer 17 is formed over the structure.

In the present embodiment, the N-well region 29 is formed having N-type impurities of a peak concentration of approximately 1×10¹⁷ cm⁻³. In addition, retro-grade wells may alternatively be formed as the P-well region 3 and N-well region 29.

Since the impurity concentration in the vicinity of the substrate surface in this case becomes lower than previously known well region, the reverse narrow channel effect tends to form with more ease. As a result, the effect of suppressing the reverse narrow channel effect increases.

Subsequently, silicon nitride layers 19, 19 are formed over the silicon oxide layer 17. The silicon nitride layers are then subjected to patterning steps to form oxidation resistant coatings 19, 19. Using the oxidation resistant coatings 19, 19 as masks, P-type impurities such as, for example, boron ions (B⁺) are implanted onto the entire structure

under the conditions of an acceleration energy of 15 keV and a dose of approximately 1.2×10¹³ cm⁻².

This ion implantation step constitutes the first ion implantation step in the semiconductor device fabrication method disclosed herein.

Since the ion implantation herein is carried out for suppressing the reverse narrow channel effect rather than forming the channel stopper, the dose for the implantation is preferably adjusted approximately equal to, or smaller than 2×10¹³ cm⁻².

(2) Following the formation of a field oxide layer 5 by the LOCOS method on the surface of P-type silicon substrate 1, the oxidation resistant coatings 19, 19 are removed.

The boron ions implanted during the process (1) are therefore distributed in boron implanted region 21 (the region designated by the mark ‘X’) under the field oxide layer 5.

Subsequently, a photoresist pattern 33 is formed to cover the N-well region 29 using well known photolithographic techniques, and boron ions (B⁺) are implanted using the photoresist pattern 33 as a mask under the conditions of an acceleration energy of 180 keV and a dose of 1×10¹³ cm⁻² to form a boron implanted region 23 (the region designated by the mark ‘◯’), thereby for a boron implanted region be formed in the P-well region 3 (FIG. 5B).

This ion implantation step constitutes the second ion implantation step in the semiconductor device fabrication method disclosed herein.

In case of impurity introduction into the channel region in the P-well region 3 for correcting threshold voltage of the NMOS transistor can be carried out under the conditions properly determined depending on desired values of threshold voltage. This is exemplified by the ion implantation of P-type impurities such as, for example, boron ions under the conditions of an acceleration energy of 10 keV and a dose of approximately 3×10¹² cm⁻².

Similarly, the impurity introduction for correcting threshold voltage of the PMOS transistor into the channel region in the N-well region 29 can be carried out under conditions properly determined depending on desired values of threshold voltage, such as, for example, an acceleration energy of 10 keV and a dose of approximately 3×10¹² cm⁻² for boron ion implantation, and an acceleration energy of 150 keV and a dose of approximately 2×10¹² cm⁻² for phosphorus ion implantation.

(3) Following the removal of the silicon oxide layer 17, gate oxide layers 13, 13 are formed. A polysilicon layer is then formed over the structure and then subjected to patterning steps to form polysilicon gates 15, 15.

Furthermore, source and drain regions (not shown) of the MOS transistors are formed by the well known process, and subjected to heat treatment steps for activating the implanted ions.

As a result, there provided in the P-well region 3 are a channel stopper region 9 which is formed of boron implanted regions 21, 23, a narrow effect controlling impurity region 7 which is formed of the boron implanted region 7 in the region in the vicinity of both ends of the channel region in the direction of channel width, and a high concentration impurity region 11 formed of the boron implanted region 23 in the regions under the channel region and the narrow effect controlling impurity region 7 spatially separated from the channel region.

In addition, a narrow effect controlling impurity region 31 is formed under the regions such as in the vicinity of both ends of the channel region in the direction of channel width and the field oxide layer 5 (FIG. 5C).

In the present embodiment, therefore, P-type impurities for forming a narrow effect controlling impurity region 7 for the NMOS transistor and a further narrow effect controlling impurity region 31 for the PMOS transistor, can be formed simultaneously using the oxidation resistant coatings 19, 19 as the masks for defining respective regions.

Therefore, the number of steps of device production decrees and the production costs can be reduced.

In the N-well region 29 in the present embodiment, N-type impurities under the field oxide layer 5 are utilized for forming the N-well region 29 and the channel stopper region for the PMOS transistor. Therefore, proper care has to be directed to the balance in concentration between N-type impurities and those in the channel stopper region for the PMOS transistor in the region under the field oxide layer 5.

That is, for the effective concentration of N-type impurities, it is necessary to retain the magnitude thereof sufficient for functioning as the channel stopper region for the PMOS transistor formed in the N-well region 29, while to control the level thereof to be suitable for achieving proper narrow channel effect. The concentration of P-type impurities in the narrow effect controlling impurity region 31 is adjusted preferably equal to, or smaller than 2×10¹³ cm¹².

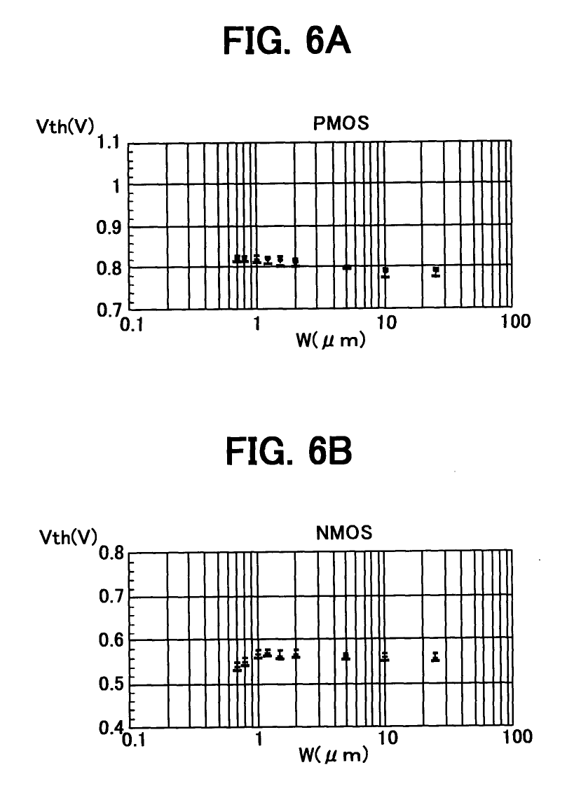

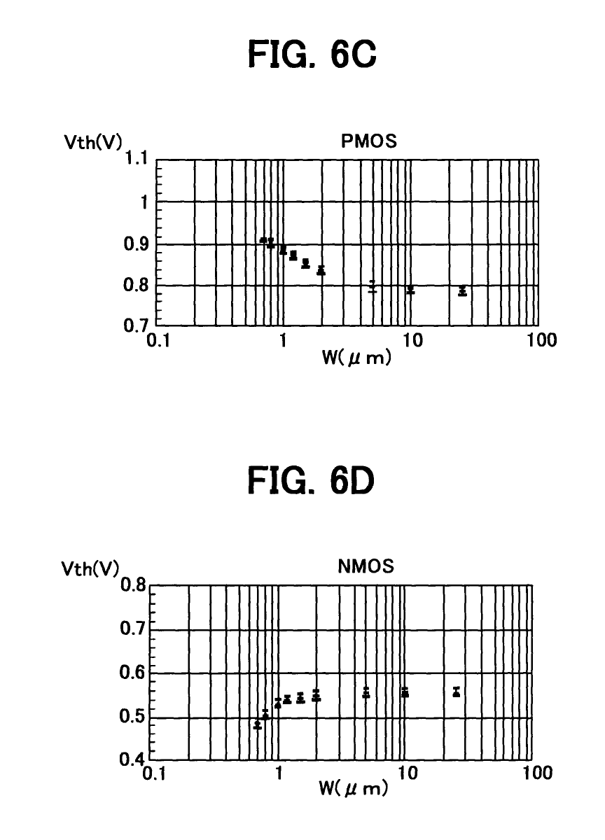

The device characteristics of several MOS transistors are shown in FIGS. 6A through 6D, each plot the threshold voltage Vₜₕ, vertically, as a function of the channel width W, horizontally.

FIGS. 6A and 6B are prepared for the PMOS and NMOS transistors fabricated as above including narrow effect controlling impurity regions disclosed herein, respectively; while FIGS. 6C and 6D are prepared for comparison for PMOS and NMOS transistors without the narrow effect controlling impurity regions, respectively.

In addition, the channel width is adjusted to be 25 am for the respective transistors.

It is clearly shown in FIGS. 6C and 6D that the narrow channel effect is quite evident for the PMOS and NMOS transistors without the narrow effect controlling impurity regions, respectively, while the narrow channel effect is considerably improved for the PMOS and NMOS transistors fabricated as above including narrow effect controlling impurity regions as shown in FIGS. 6A and 6B, respectively.

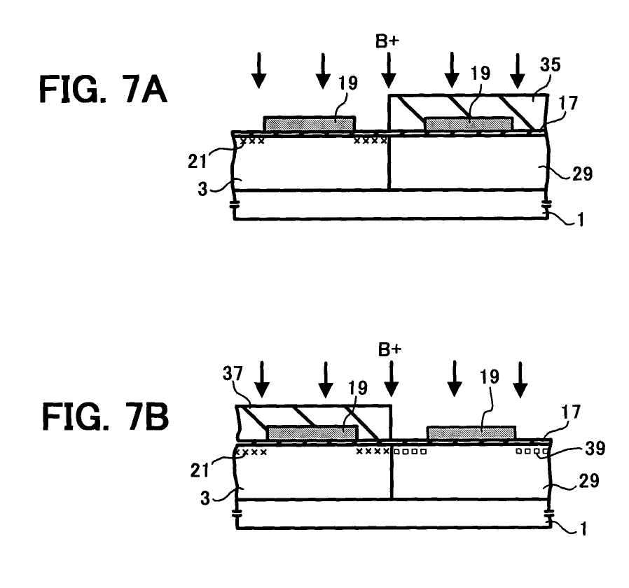

FIGS. 7A and 7B are each cross-sectional views along the channel width direction illustrating the portion of the method for manufacturing semiconductor devices during various stages in the process.

The components in the drawings similar to those in FIGS. 5A through 5C are shown with identical numerical representations and detailed description thereof is herein abbreviated.

(1-1) Following the formation of an N-well region 29 and P-well region 3 in a P-type silicon substrate 1, a silicon oxide layer 17 is formed over the structure. Subsequently, silicon nitride layers are formed over the silicon oxide layer 17.

A photoresist pattern 35 is then formed to cover the N-well region 29 using well known photolithographic techniques, and P-type impurities such as, for example, boron ions (B⁺) are implanted using the photoresist pattern 35 as a mask under the conditions of an acceleration energy of 15 keV and a dose of 1.5×10¹³ cm⁻² to thereby form a boron implanted region 21 (the region designated by the mark ‘X’) as shown in FIG. 7A.

(1-2) Following the removal of the photoresist pattern 35, a further photoresist pattern 37 is formed to cover the P-well region 3 using well known photolithographic techniques.

P-type impurities such as, for example, boron ions (B⁺) are then implanted into the N-well region 29 using the photoresist pattern 37 as a mask under the conditions of an acceleration energy of 15 keV and a dose of 1.5×10¹³ cm⁻² to thereby form a boron implanted region 39 (the region designated by the mark ‘□’) as shown in FIG. 7B.

Subsequently, a field oxide layer 5 is formed by the process (2) described earlier in reference to FIG. 5B.

In addition, there formed by the process (3) described earlier in reference to FIG. 5C are a narrow effect controlling impurity region 7, channel stopper region 9, high concentration impurity region 11, gate oxide layer 13, polysilicon gate 15 and narrow effect controlling impurity regions 31.

The narrow effect controlling impurity regions 31 is formed of the boron implanted region 39.

In the present embodiment, therefore, the care directed earlier to the balance in concentration may not be necessary between the two mutually opposing conductivity types during the ion implantation processes, one the process (1-1) for forming the narrow effect controlling impurity region 7 and the process (1-1) for forming the narrow effect controlling impurity region 7, and the other the process (1-2) for forming the narrow effect controlling impurity regions 31.

Therefore, the range of control can increase for the narrow channel effect.

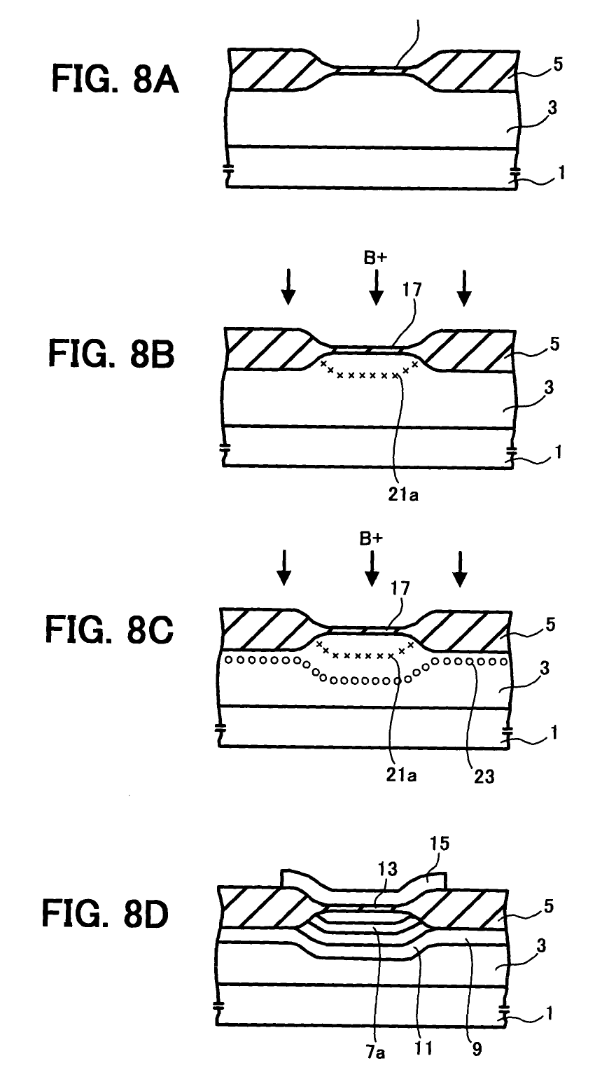

FIGS. 8A through 8D are each cross-sectional views along the channel width direction illustrating a further method for manufacturing a semiconductor device during various stages in the process and FIG. 8D illustrates the fabricated enhancement-mode NMOS transistor as the semiconductor device according to another embodiment disclosed herein.

In addition, the components in the drawings similar to those in FIGS. 2A through 2C are shown with identical numerical representations and detailed description thereof is herein abbreviated.

(1) Following the formation of a P-well region 3 in a P-type silicon substrate 1, a silicon oxide layer 17, an oxidation resistant coating, and a field oxide layer 5 by the LOCOS method are formed in that order.

It is noted that ion implantation has not been made for forming a narrow effect controlling impurity region 7 (FIG. 8A).

(2) A photoresist pattern is formed (not shown) having openings over several regions such as one for forming a narrow effect controlling impurity region and the other for a channel stopper region.

By ion implantation techniques using the photoresist pattern as a mask, P-type impurities such as, for example, boron ions (B⁺) are implanted under the conditions of an acceleration energy of 50 keV and a dose of 1.2×10¹³ cm⁻².

The thus implanted boron ions are distributed in a boron implanted region 21a (the region designated by the mark ‘X’). The depth of this region is determined by the thickness of overlying the field oxide layer 5 and silicon oxide layer 17, formed over the P-well region 3.

That is, no boron ion is implanted into the P-well region toward the middle of the field oxide layer 5, some boron ions into the region relatively shallow under the field oxide layer 5, while relatively deep under the silicon oxide layer 17 (FIG. 8B).

This ion implantation step constitutes the first ion implantation step in the semiconductor device fabrication method.

Using the same photoresist pattern as a further mask, boron ions (B⁺) are implanted under the conditions of, for example, an acceleration energy of 180 keV and a dose of 1×10¹³ cm⁻².

The boron ions implanted during the process are distributed in a boron implanted region 23 (the region designated by the mark ‘◯’). The depth of this region is deeper than the region 21a (FIG. 8C).

This ion implantation step constitutes the second ion implantation step in the semiconductor device fabrication method.

In case of impurity introduction into the channel region in the P-well region 3 for correcting threshold voltage of the NMOS transistor can be carried out under the conditions properly determined depending on desired values of threshold voltage. This is exemplified by the ion implantation of P-type impurities such as, for example, boron ions under the conditions of an acceleration energy of 10 keV and a dose of approximately 3×10 cm⁻².

(3) Following the removal of the silicon oxide layer 17, gate oxide layers 13 is formed to a thickness of approximately 7 nm.

A polysilicon layer is then formed over the structure and then subjected to patterning steps to form a polysilicon gate 15.

Furthermore, source and drain regions (not shown) of a MOS transistor are formed by the well known process, and subjected to heat treatment steps for activating the implanted ions.

As a result, there provided in the P-well region 3 are a narrow effect controlling impurity region 7a is formed, out of the boron implanted region 21a, under the regions such as in the vicinity of both ends of the channel region in the direction of channel width and the field oxide layer 5, a high concentration impurity region 11 formed of the boron implanted region 23 in the regions under the narrow effect controlling impurity region 7a spatially separated from the channel region, and a channel stopper region 9 which is formed of boron implanted region 23 (FIG. 8D).

In the present embodiment, therefore, since the channel region, channel stopper region 9, and high concentration impurity region 11 are formed spatially separated from each other, the NMOS transistor can be formed including the narrow effect controlling impurity region 7a provided in the region in the vicinity of both ends of the channel region in the direction of channel width.

Therefore, either the reverse narrow channel effect or the narrow channel effect is properly controlled, and the enhancement-mode NMOS can be fabricated unaffected by the reverse narrow channel effect or the narrow channel effect.

Furthermore, the ion implantation process (2) for forming the narrow effect controlling impurity region 7a and the further ion implantation process (3) for forming the channel stopper region 9 and high concentration impurity region 11 are carried out using the same photoresist pattern as the mask, whereby production costs can be reduced.

Although the method for manufacturing a semiconductor device according to the present embodiment has been adapted to the fabrication of enhancement-mode NMOS transistors, it is not intended to be limiting.

For example, the present method may also be adapted to depletion-mode NMOS transistors by implanting N-type impurities in place of the aforementioned P-type ions in the ion implantation process (2).

In addition, although the method has been described on the P-well region 3 of the NMOS transistor in the present embodiment to include the narrow effect controlling impurity region 7, channel stopper region 9 and the high concentration impurity region 11, it is not intended to be limiting.

For example, the narrow effect controlling impurity region, channel stopper region and high concentration impurity region may be formed in the N-well region of PMOS transistor.

In the method for fabricating semiconductor devices provided with PMOS and NMOS transistors, in particular, the optimization of the reverse narrow channel effect and narrow channel effect becomes feasible with high precision through adapting the present method to both PMOS and NMOS transistors.

Furthermore, although the field oxide layer 5 is formed by the LOCOS method in the embodiments disclosed herein in the method for manufacturing semiconductor devices,

the field oxide layer 5 may also be formed alternatively by other method such as, for example, poly-buffered LOCOS method.

In the present case, the pertinent layers for the transistors may be provided in the aforementioned process (1) or (1-1). That is, following the formation of the silicon oxide layer 17, the polysilicon layer is formed thereon to a thickness ranging from 20 to 50 nm, and the oxidation resistant coating of silicon nitride layer is formed further thereon.

It may be added that the description on the poly-buffered LOCOS method is found also in Japanese Laid-Open Patent Application No. 9-45677.

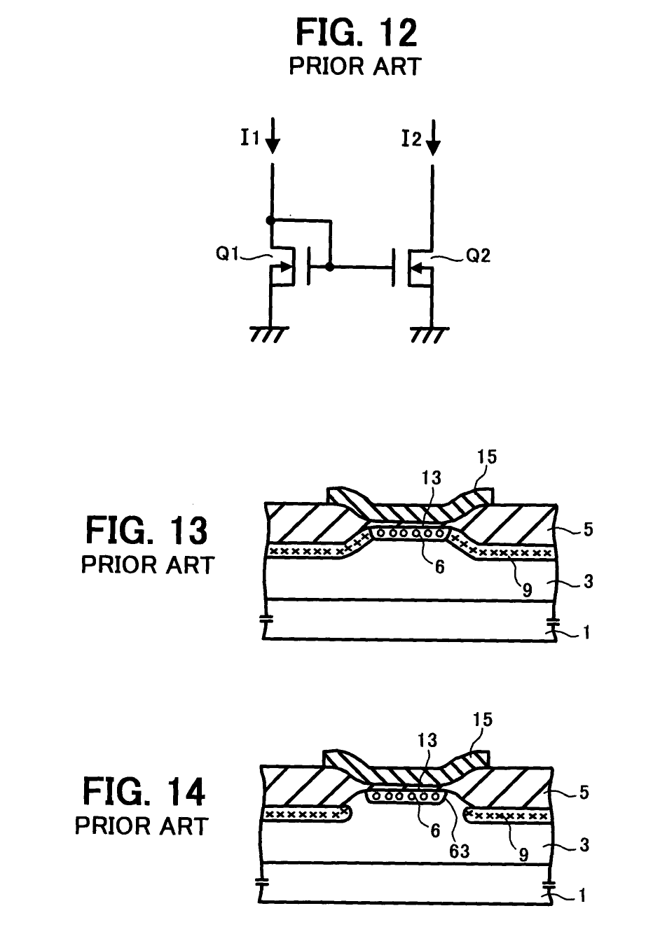

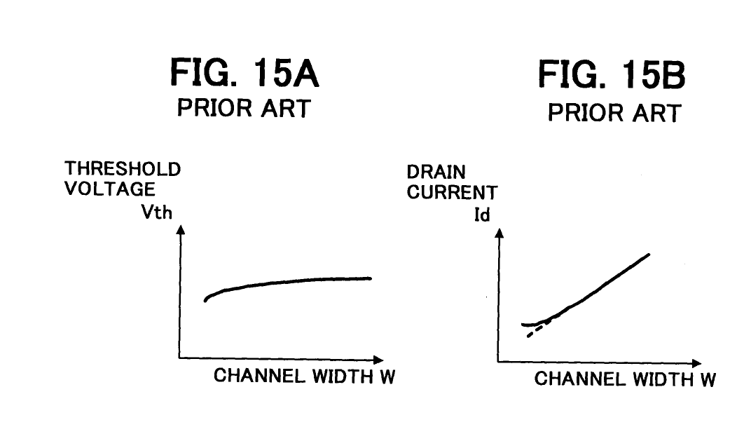

The MOS transistors disclosed herein can suitably be adapted to semiconductor apparatus such as, for example, the current mirror circuit as illustrated in FIG. 12.

As described earlier, the reverse narrow channel effect and narrow channel effect are properly controlled in the MOS transistors disclosed herein. By incorporating the MOS transistors into the current mirror circuit, therefore, the precision in power output increases.

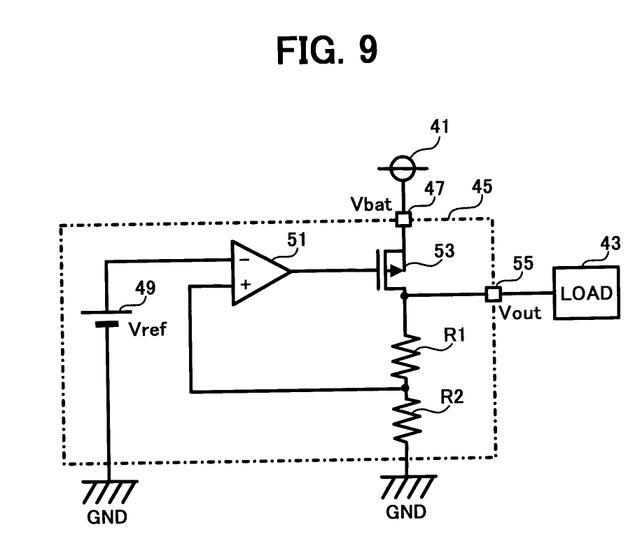

FIG. 9 is an electrical schematic diagram illustrating a semiconductor apparatus provided with a constant voltage generation circuit as an analogue circuit according to another embodiment disclosed herein.

Referring to FIG. 9, a constant voltage generation circuit 45 is designed to stably supply the source power output from a direct current source 41 to a load 43.

The constant voltage generation circuit 45 is provided with an input terminal (V_{bat}) 47 to which the direct current source 41 is connected, a standard voltage generation circuit (V_{ref}) 49 as a reference voltage source, an operational amplifier 51, a P-channel type MOS transistor (or PMOS) 53 to constitute an output driver, dividing resistors R1 and R2, and an output terminal (Vₒᵤₜ) 55.

In the constant voltage generation circuit 45, its output terminal is connected to a gate electrode of the PMOS 53, the reference voltage V_{ref} from the reference voltage source is applied to the inverting input terminal of operational amplifier 51; the voltage, which is obtained by diving Vₒᵤₜ by means of dividing resistors R1 and R2, is applied to the noninverting input terminal of operational amplifier 51; and the divided voltage by the dividing resistors, R1 and R2, is then adjusted to be equal to the reference voltage V_{ref}.

Also in the constant voltage generation circuit 45, a current mirror circuit is provided in the operational amplifier 51 incorporating the MOS transistors disclosed herein.

By incorporating the MOS transistors as described above, the precision in power output from the current mirror circuit is improved, whereby the accuracy in comparison capability of the function of the operational amplifier 51 and accordingly the precision in power output of constant voltage generation circuit 45 can be increased.

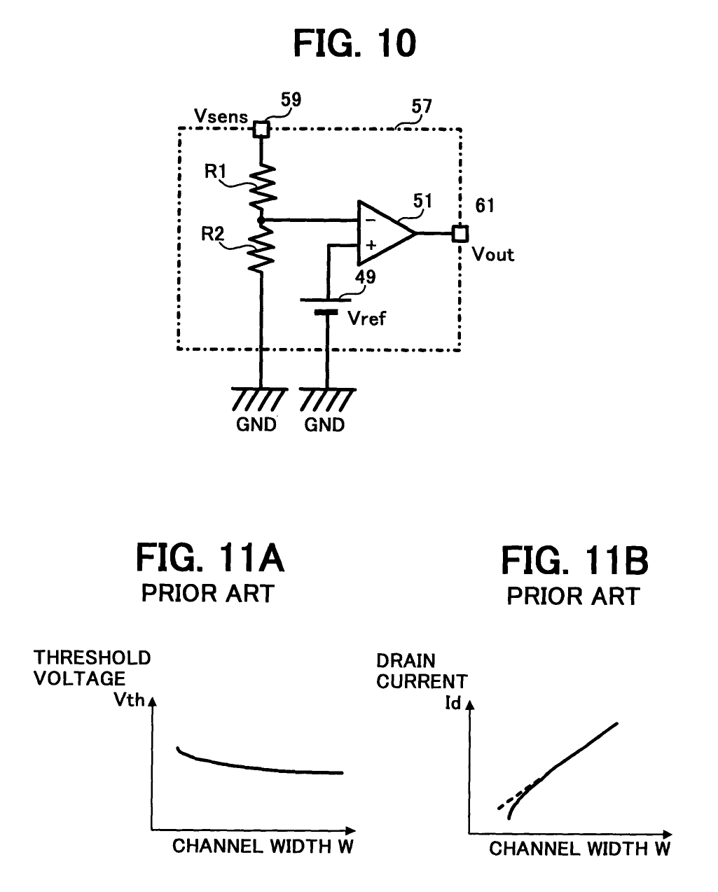

FIG. 10 is an electrical schematic diagram illustrating a further semiconductor apparatus provided with a voltage detection circuit as an analogue circuit according to another embodiment disclosed herein.

Referring to FIG. 10, in the voltage detection circuit 57 including an operational amplifier 51, a standard voltage generation circuit 49 is connected to the inverting input terminal of the operational amplifier 51 to which the reference voltage V_{ref} is applied.

The voltage, which is input from a certain terminal to be subjected presently to voltage measurement, is divided by dividing resistors, R1 and R2, and subsequently input to the noninverting input terminal of operational amplifier 51. The output voltage from the operational amplifier 51 is forwarded to the exterior by way of an output terminal (Vₒᵤₜ) 61.

This voltage detection circuit 57 is designed to operate as follows.

If the voltage at the terminal to be presently measured is relatively high and accordingly the voltage divided by dividing resistors, R1 and R2, is higher than V_{REF}, the output of the operational amplifier 51 becomes high ‘H’; while this output changes to low ‘L’, when the voltage at the terminal decreases and accordingly the voltage divided by dividing resistors becomes lower than V_{REF}, the output of the operational amplifier 51.

In the voltage detection circuit 57, a further current mirror circuit is provided in the operational amplifier 51 incorporating the MOS transistors disclosed herein.

By including the MOS transistors as described above, the precision in power output from the current mirror circuit is improved, whereby the accuracy in comparison capability of the function of the operational amplifier 51 and accordingly the precision in the output of voltage detection circuit 57 can increase.

Although the MOS transistors disclosed herein have been discerned as incorporated into the semiconductor apparatus such as the constant voltage generation circuit and voltage detection circuit, the present disclosure is not limited to above embodiments, but may also be adaptable to other semiconductor apparatuses generally including MOS transistors.

It is apparent from the above description including the examples, the MOS transistors disclosed herein are advantageous over previously known similar devices and can be incorporated into various circuits and apparatuses.

As an example, the MOS transistor disclosed herein includes an impurity region for controlling narrow effect formed in the vicinity of both ends of a channel region in the direction of channel width, and a high concentration impurity region formed with an impurity concentration approximately equal to that of the channel stopper region at the location deeper than the channel stopper region.

The reverse narrow channel effect or the narrow channel effect can therefore be controlled by suitably adjusting the impurity concentration in the narrow effect controlling impurity region.

In the MOS transistor, another impurity region for controlling narrow effect is formed preferably having the same kind, and the same concentration, of impurities as those of the impurity region for controlling narrow effect, in the region for forming another MOS transistor of a second conductivity type (opposite to that of the first conductivity type) in the vicinity of both ends of a channel region in the direction of channel width.

As a result, in the case where both NMOS and PMOS transistors are included, a first narrow effect controlling impurity region for the NMOS or PMOS transistor, and another narrow effect controlling impurity region for the PMOS or NMOS transistor, can be formed simultaneously. Therefore, the number of steps of device production decreases and the production costs can be reduced.

In addition, since the impurities in the impurity region for controlling the narrow effect may have the conductivity type opposite to that of the high concentration impurity region, proper control of the reverse narrow channel effect or narrow channel effect becomes feasible for depletion-mode NMOS transistors by implanting impurity ions of the conductivity type opposite to that of ions of the channel stopper.

In another aspect, a further semiconductor apparatus is provided including a current mirror circuit which incorporate MOS transistors disclosed herein. Since the MOS transistors disclosed herein is incorporated into the current mirror circuit, the precision in power output for the current mirror circuit can be improved.

In addition, in a further semiconductor apparatus provided herein including an analog circuit consisting dividing resistors for dividing a voltage to be measured and supplying a divided voltage, a reference voltage source for supplying a reference voltage, and an operational amplifier for comparing the divided voltage with reference voltage, the operational amplifier is formed to include the above noted current mirror circuit.

Since the analog circuit is formed including the abovementioned current mirror circuit, the precision in power output thereof can be improved.

A method is provided herein including the steps of (A) forming an oxidation resistant coating for defining the region for forming the field oxide layer; (B) implanting ions of a first impurity for controlling reverse narrow channel effect into the semiconductor substrate using the oxidation resistant coating as a mask, as a first implantation process; (C) selectively forming a field oxide layer through heat treatment on the surface of the semiconductor substrate; and (D) implanting ions of a second impurity from above the field oxide layer into the semiconductor substrate for forming a channel stopper region at the location deeper than the first impurity channel stopper region at least in the vicinity of both ends of the channel region in the direction of channel width of the MOS transistor, as a second implantation process.

Therefore, the noted MOS transistor can be formed properly.

In addition, the present method for manufacturing the noted semiconductor apparatus may alternatively be carried including the step of, prior to the first implantation process (A), forming a well region of a first conductivity type and a further well region of a second conductivity type opposite to that of the first conductivity type; in which the first implantation process (B) is implemented such that the ions of the first conductivity type are implanted, as the ions of the first impurity, into the well region of the first conductivity type and the further well region of the second conductivity type; and which the second implantation process (D) is implemented with a mask pattern covering the region of the further well region of the second conductivity type such that the ions of the first conductivity type are implanted as the ions of the second impurity into the well region of the first conductivity type.

As a result, in the case where both NMOS and PMOS transistors are included, the number of steps of device production decreases and the production costs can be reduced.

A further method is herein provided including the steps of (A) forming a field oxide layer selectively through heat treatment on the surface of the semiconductor substrate, (B) forming a mask pattern having openings over the regions for forming a narrow effect controlling impurity region and the channel stopper region, and subsequently implanting ions of a first impurity for controlling the reverse narrow channel effect into the semiconductor substrate using the mask pattern as a mask, as a first implantation process, and (C) implanting ions of a second impurity into the semiconductor substrate using the same mask pattern for forming a channel stopper region at the location deeper than the first impurity channel stopper region at least in the vicinity of both ends of the channel region in the direction of channel width of the MOS transistor, as a second implantation process.

Since the same mask pattern is used for the ion implantation processes, production costs can be reduced.

In addition, during the above noted methods the ions of the first impurity used in the first implantation process may have a conductivity type opposite to that of the second impurity used in the second implantation process.

As a result, the methods for manufacturing a semiconductor device disclosed may also be adapted to depletion-mode NMOS transistors by implanting impurity ions of the conductivity type opposite to that of ions of the channel stopper, whereby the reverse narrow channel effect or narrow channel effect can properly be suppressed.

The process steps set forth in the present description on the fabrication of MOS transistors and semiconductor apparatuses incorporating the transistors may be implemented using conventional general purpose microprocessors, programmed according to the teachings in the present specification, as will be appreciated to those skilled in the relevant arts. Appropriate software coding can readily be prepared by skilled programmers based on the teachings of the present disclosure, as will also be apparent to those skilled in the relevant arts.

The present specification thus include also a computer-based product which may be hosted on a storage medium, and include instructions which can be used to program a microprocessor to perform a process in accordance with the present disclosure. This storage medium can include, but not limited to, any type of disc including floppy discs, optical discs, CD-ROMs, magneto-optical discs, ROMs, RAMs, EPROMs, EEPROMs, flash memory, magnetic or optical cards, or any type of media suitable for storing electronic instructions.

Additional modifications and variations of the present invention are possible in light of the above teachings. It is therefore to be understood that within the scope of the appended claims, the invention may be practiced other than as specifically described herein.

What is claimed as new and desired to be secured by letters patent of the united states is:

1. A semiconductor apparatus, comprising:
a field oxide layer for device isolation formed on a semiconductor substrate;
a channel stopper region formed under said field oxide layer; and
a MOS transistor of a first conductivity type electrically isolated by said field oxide layer and said channel stopper region;
said MOS transistor comprising
an impurity region for controlling a narrow channel effect formed in a vicinity of both ends of a channel region in a direction of channel width; and
a high concentration impurity region formed having an impurity concentration approximately equal to that of said channel stopper region at a location deeper than said channel stopper region.

2. The semiconductor apparatus according to claim 1, further comprising:
a further impurity region for controlling a narrow channel effect formed having a same kind, and a same concentration, of impurities as those of said impurity region for controlling said narrow channel effect, in a region for forming a further MOS transistor of a second conductivity type opposite to that of said first conductivity type in a vicinity of both ends of a channel region in a direction of channel width.

3. The semiconductor apparatus according to claim 1, wherein:
said impurities in said impurity region for controlling said narrow channel effect have a conductivity type opposite to that of said high concentration impurity region.

4. A semiconductor apparatus comprising a current mirror circuit, said current mirror circuit including at least a MOS transistor recited in anyone of claims 1, 2 and 3.

5. A semiconductor apparatus, comprising:
an analog circuit including at least dividing resistors for dividing a voltage to be measured and supplying a divided voltage, a reference voltage source for supplying a reference voltage, and an operational amplifier for comparing said divided voltage with said reference voltage,
wherein:
said operational amplifier includes at least said current mirror circuit of claim 4.

6. A method for manufacturing a semiconductor apparatus, said semiconductor apparatus including at least a field oxide layer for device isolation formed on a semiconductor substrate; a channel stopper region formed under said field oxide layer; and a MOS transistor of a first conductivity type electrically isolated by said field oxide layer and said channel stopper region;
comprising the steps of:
(A) forming an oxidation resistant coating for defining a region for forming said field oxide layer;
(B) implanting ions of a first impurity for controlling a reverse narrow channel effect into said semiconductor substrate using said oxidation resistant coating as a mask, as a first implantation process;
(C) selectively forming a field oxide layer through heat treatment on a surface of said semiconductor substrate; and
(D) implanting ions of a second impurity from above said field oxide layer into said semiconductor substrate for forming a channel stopper region at a location deeper than said first impurity channel stopper region at least in a vicinity of both ends of said channel region in a direction of channel width of said MOS transistor, as a second implantation process.

7. The method for manufacturing a semiconductor apparatus according to claim 6, further comprising the step of:
prior to said first implantation process (A), forming a well region of a first conductivity type and a further well region of a second conductivity type opposite to that of said first conductivity type;
wherein:
said first implantation process (B) is implemented such that said ions of said first conductivity type are implanted, as said ions of said first impurity, into said well region of said first conductivity type and said further well region of said second conductivity type; and
said second implantation process (D) is implemented with a mask pattern covering a region of said further well region of said second conductivity type such that said ions of said first conductivity type are implanted as said ions of said second impurity into said well region of said first conductivity type.

8. The method for manufacturing a semiconductor apparatus according to claim 6, wherein:
said ions of said first impurity used in said first implantation process have a conductivity type opposite to that of said ions of said second impurity used in said second implantation process.

9. A method for manufacturing a semiconductor apparatus, said semiconductor apparatus including at least a field oxide layer for device isolation formed on a semiconductor substrate; a channel stopper region formed under said field oxide layer; and a MOS transistor of a first conductivity type electrically isolated by said field oxide layer and said channel stopper region;
comprising the steps of:
(A) forming an oxidation resistant coating for defining a region for forming said field oxide layer and subsequently a field oxide layer selectively through heat treatment on a surface of said semiconductor substrate;
(B) forming a mask pattern having openings over regions for forming a narrow effect controlling impurity region and said channel stopper region, and subsequently implanting ions of a first impurity for controlling a reverse narrow channel effect into said semiconductor substrate using said mask pattern as a mask, as a first implantation process; and
(C) implanting ions of a second impurity into said semiconductor substrate using said mask pattern as a mask for forming a channel stopper region at a location deeper than said first impurity channel stopper region at least in a vicinity of both ends of said channel region in a direction of channel width of said MOS transistor, as a second implantation process.

10. The method for manufacturing a semiconductor apparatus according to claim 9, wherein:
said ions of said first impurity used in said first implantation process have a conductivity type opposite to that of said ions of said second impurity used in said second implantation process.

11. A semiconductor apparatus comprising current mirror circuit means, said current mirror circuit means including at least a MOS transistor recited in anyone of claims 1, 2 and 3.

12. A semiconductor apparatus, comprising:
analog circuit means including at least dividing resistor means for dividing a voltage to be measured and supplying a divided voltage, reference voltage source means for supplying a reference voltage, and operational amplifier means for comparing said divided voltage with said reference voltage,
wherein:
said operational amplifier means includes at least said current mirror circuit means of claim 11.
